(19) United States
(12) Patent Application Publication
(10) Pub. No.: US 2002/0031674 A1
(43) Pub. Date: Mar. 14, 2002

(54) Low-emissivity glass coatings having a layer of silicon oxynitride and methods of making same

(76) Inventor: Ronald E. Laird, Washtenaw, MI (US)

Correspondence Address: NIXON & VANDERHYE P.C., 8th Floor, 1100 North Glebe Road, Arlington, VA, 22201, US

(21) Appl. No.: 09/793,406

(22) Filed: Feb. 27, 2001

Related U.S. Application Data
(60) Provisional application No. 60/187,040, filed on Mar. 6, 2000.

(51) Int. Cl. B32B 9/00; C23C 14/34

(52) U.S. Cl. 428/472; 428/428; 428/432; 428/336; 428/216; 204/192.15; 204/192.22; 204/192.23

(57) ABSTRACT

Low-E glass coatings having improved durability and transmissivity. In particularly preferred forms, the present invention is embodied in surface-coated glass articles which include a glass substrate and a multiple layer coating on a surface of the glass substrate, wherein the coating is comprised of a layer of a transparent dielectric material adjacent the surface of the glass substrate, a layer of nickel or nichrome, and a layer of silicon oxynitride interposed between said layer of dielectric material and said layer of nickel or nichrome. The thickness of the silicon oxynitride layer is most preferably between about 25-200 Å.

### FIELD OF THE INVENTION

The present invention relates generally to coatings for glass substrates. More specifically, the present invention relates to glass substrate coatings which exhibit low emissivity (so-called “low-E” coatings) and substantially no color characteristics.

### BACKGROUND AND SUMMARY OF THE INVENTION

Low-E coatings for glass are well known. In this regard, commonly owned U.S. Pat. Nos. 5,344,718, 5,425,861, 5,770,321, 5,800,933 (the entire content of each being incorporated expressly herein by reference) disclose coatings formed of a multiple layer coating “system”. Generally, such conventional multiple layer low-E glass coatings have a layer of a transparent dielectric material (e.g., TiO₂, BiO₃, PbO or mixtures thereof) adjacent the glass substrate and a sequence of multiple layers of, for example, Si₃N₄, nickel (Ni), nichrome (Ni:Cr), nitrided nichrome (NiCrN) and/or silver (Ag). These conventional low-E coatings are, moreover, heat-treatable—that is, the coating is capable of being subjected to the elevated temperatures associated with conventional tempering, bending, heat-strengthening or heat-sealing processes without significantly adversely affecting its desirable characteristics.

While the conventional low-E coating systems disclosed in the above-cited U.S. patents are satisfactory, there exists a continual need to improve various properties of low-E coating systems generally. For example, continued improvements in the durability and/or color (or more accurately, lack of color) characteristics in low-E glass coatings are desired. Improvements in such characteristics are important to ensure that the coatings retain their low-E property for prolonged periods of time (even after being subjected to potentially abrasive environment encountered during the manufacturing process—e.g., the washing and cutting of glass articles having such low-E coatings) and have the desired light transmission properties. It is toward fulfilling such needs that the present invention is directed.

Broadly, the present invention is embodied in low-E glass coatings having improved durability and transmissivity. In particularly preferred forms, the present invention is embodied in surface-coated glass articles which include a glass substrate and a multiple layer coating on a surface of the glass substrate, wherein the coating is comprised of at least one layer of a transparent dielectric material adjacent the surface of the glass substrate, a layer of nickel or nichrome, and a layer of silicon oxynitride interposed between said layer of dielectric material and said layer of nickel or nichrome. The thickness of the silicon oxynitride layer is most preferably between about 25-200 Å.

These and other aspects and advantages will become more apparent after careful consideration is given to the following detailed description of the preferred exemplary embodiments thereof.

### BRIEF DESCRIPTION OF THE ACCOMPANYING DRAWINGS

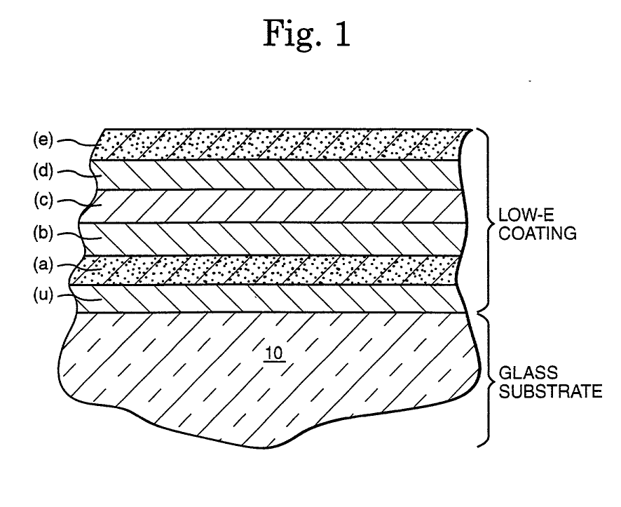

Reference will hereinafter be made to the accompanying drawings, wherein FIG. 1 is a greatly enlarged cross-sectional schematic representation of a surface-coated glass article of this invention which includes a glass substrate and a multiple layer low-E coating system coated on a surface of the glass substrate.

### DETAILED DESCRIPTION OF THE INVENTION

Accompanying FIG. 1 depicts in a schematic fashion one particularly preferred embodiment of the present invention. In this regard, the multiple layer low-E coating of the present invention will necessarily be applied onto a glass substrate 10 which is, in and of itself, highly conventional. Specifically, the glass substrate 10 is most preferably made by a conventional float process and is thus colloquially known as “float glass”. Typical thicknesses of such float glass may be from about 2 mm to about 6 mm, but other glass thicknesses may be employed for purposes of the present invention. The composition of the glass forming the substrate 10 is not critical, but typically the glass substrate will be formed of one of the soda-lime-silica types of glass well known to those in this art.

The process and apparatus used to form the various layers comprising the low-E coating of the present invention may be a conventional multi-chamber (multi-target) sputter-coating system such as that disclosed generally in U.S. Pat. No. 5,344,718 (the entire content of which is incorporated expressly herein by reference). One particularly preferred sputter-coating system is commercially available from Airco, Inc. As is well known, the glass substrate 10 is advanced sequentially through the contiguous chambers or zones which have respective atmospheres to form sputter-coating layers of desired constituency and thickness.

As depicted in FIG. 1, one particularly preferred low-E coating may be formed of the following layers and layer thicknesses (identified sequentially from adjacent the glass substrate 10 toward the outside):

| | | Thickness | Thickness |
|---|---|---|---|
| Layer | Constituent | Range (Å) | Preferred (Å) |
| (u) | transparent dielectric | about 100-200 | about 125 |
| (a) | silicon oxynitride | about 25-200 | about 125 |
| (b) | nichrome | about 2-20 | about 10 |
| (c) | silver | about 100-200 | about 145 |
| (d) | nichrome | about 2-20 | about 10 |
| (e) | Si₃N₄ | about 350-600 | about 480 |

The undercoat layer (u) in FIG. 1 is selected so it has an index of refraction at 550 nm wavelength of about 2.5 to about 2.6, and preferably about 2.52. Preferably, the undercoat layer (u) includes at least one transparent dielectric selected from TiO₂, BiO₃, PbO and mixtures thereof. TiO₂ is especially preferred. The undercoat (u) may be a single layer of such dielectric materials or may be comprised of multiple layers of the same, or different, dielectric material.

In sputter-coating many of the layers, silicon (Si) targets are employed. Optionally, the Si may be admixed with an amount of stainless steel (e.g., no. 316) to achieve the desired end amount in the film layer. Optionally, aluminum (Al) may also be employed as a dopant in relatively small amounts (e.g., 8% by weight).

Important to the present invention, the silicon oxynitride layer (a) is interposed between the transparent dielectric underlayer (u) and the nichrome layer (b). Most preferably, the silicon oxynitride layer (a) is sputter-coated in a gaseous atmosphere comprised of nitrogen, oxygen and argon, wherein at least between about 5% to about 50%, most preferably about 10%, of the gas is oxygen. A particularly preferred atmosphere for sputter-coating the silicon oxynitride layer (a) is about 30% N₂, about 10% O₂ and about 60% Ar₂.

The silicon oxynitride layer (a) is monolithic in its thickness. That is, by “monolithic” is meant that the layer (a) has a substantially uniform amount of silicon oxynitride between its interfacial boundaries with layers (u) and (b), respectively. Thus, the amount of silicon oxynitride does not change appreciably throughout the entire thickness dimension of layer (a).

A greater understanding of this invention will be achieved by careful consideration of the following non-limiting Examples.

### EXAMPLES

### Example I

A low emissivity coating comprised of layers (u) through (e) as identified generally in FIG. 1 was applied onto a float glass substrate using a multi-chamber sputter-coater (Airco, Inc.) at a line speed of 175 in/min under the following conditions:

Layer (u): TiO2—6 Dual C-MAG cathodes (12 Ti metal targets)

Three cathodes are in the first coat zone (CZ1) and three are in the second Coat Zone (CZ2).

Each coat zone is run identically—DC Reactive sputtering

Pressure=3.5 mTorr

Gas Ratio (60% O2/40% Ar)

Total gas flow=1850 (sccm)

Power—˜80 kW per target

Layer (a): SiOxNy—3 Dual C-MAG cathodes (6 Plasma Sprayed Si/Al targets ˜8% Al)

Bi-Polar Pulsed DC power

Pressure=2.5 mTorr

Gas Ratio (30% N2, 10% O2, 60% Ar)

Total gas flow=1425 sccm

Power—˜7 kW per target

Layer (b): NiCr—1 Planar cathode (80% Ni/20% Cr)

DC Sputtered

Pressure=2.5 mTorr

Gas Ratio (100% Ar)

Total gas flow=1125 sccm

Power—˜3.0 kW per target

Layer (c): Ag—1 Planar Cathode (100% Silver)

DC Sputtered

Pressure=2.5 mTorr

Gas Ratio (100% Ar)

Total gas flow=1125 sccm

Power—˜6.75 kW per target

Layer (d) NiCr—1 Planar cathode (80% Ni/20% Cr)

DC Sputtered

Pressure=2.5 mTorr

Gas Ratio (100% Ar)

Total gas flow=1125 sccm

Power—˜3.0 kW per target

Layer (e): SixNy—3 Dual C-MAG cathodes (6 Plasma Sprayed Si/Al targets ˜8% Al)

Bi-Polar Pulsed DC power

Pressure=2.5 mtorr

Gas Ratio (60% N2, 40% Ar)

Total gas flow=2050 sccm

Power—˜28 kW per target

### Example II

Coated 6″×17″ glass test samples cut from larger glass sheets nominally 84 inches in width and having lengths varying from 72 inches, 130 inches and 144 inches which were prepared according to Example I were subjected to mechanical durability testing. Specifically, a 2″×4″×1″ nylon brush was cyclically passed over the coating layer of each test sample in 500 cycles employing 150 grams of weight. The coated glass samples of the invention exhibited no damage after being subjected to such mechanical durability testing.

While the invention has been described in connection with what is presently considered to be the most practical and preferred embodiment, it is to be understood that the invention is not to be limited to the disclosed embodiment, but on the contrary, is intended to cover various modifications and equivalent arrangements included within the spirit and scope of the appended claims.

What is claimed is:

1. A surface-coated glass article comprised of a glass substrate and a multiple layer coating on a surface of the glass substrate, wherein said coating includes at least one layer of a transparent dielectric material adjacent the surface of the glass substrate, a layer of nickel or nichrome, and a layer of silicon oxynitride interposed between said layer of dielectric material and said layer of nickel or nichrome.

2. The surface-coated glass article as in claim 1, wherein the layer of silicon oxynitride has a thickness of between about 25-200 Å.

3. The surface-coated glass article of claim 1, wherein the dielectric material is at least one selected from the group consisting of TiO₂, BiO₃, PbO and mixtures thereof.

4. The surface-coated glass article as in claim 1, which further comprises, from the layer of nickel or nichrome outwardly, a layer of silver, a layer of nichrome, and a layer of Si₃N₄.

5. A surface-coated glass article comprised of a glass substrate and a multiple layer coating comprising the following layers formed on a surface of the glass substrate, from the surface outwardly:
(1) a layer of transparent dielectric material;
(2) a layer of silicon oxynitride;
(3) a first layer of nickel or nichrome;
(4) a layer of silver;
(5) a second layer of nickel or nichrome;
(6) a layer of Si₃N₄.

6. The surface-coated glass article as in claim 5, wherein the layer of silicon oxynitride has a thickness of between about 25-200 Å.

7. The surface-coated glass article of claim 5, wherein the dielectric material is at least one selected from the group consisting of TiO₂, BiO₃, PbO and mixtures thereof.

8. The surface-coated glass article of claim 7, wherein the dielectric material has an index of refraction (n) of about 2.5-2.6 as measured at a wavelength of 550 nanometers.

9. The surface-coated glass article of claim 5, wherein the layers have the following thicknesses in Angstroms:
(1) between about 100-200;
(2) between about 25-200;
(3) between about 2-20;
(4) between about 100-200;
(5) between about 2-20; and
(6) between about 350-600.

10. The surface-coated glass article of claim 9, wherein the layers have the following thicknesses in Angstroms:
(1) about 125;
(2) about 125;
(3) about 10;
(4) about 145;
(5) about 10; and
(6) about 480.

11. A method of making a surface-coated glass article comprising sputter-coating on a surface of a glass substrate a multiple layer coating comprised of a layer of a transparent dielectric material adjacent the surface of the glass substrate, a layer of nickel or nichrome, and a layer of silicon oxynitride interposed between said layer of dielectric material and said layer of nickel or nichrome.

12. The method of claim 11, wherein said layer of silicon oxynitride is formed by sputter-coating in a gaseous atmosphere comprised of nitrogen, oxygen and argon, wherein the oxygen is present in the atmosphere in an amount between about 5 to about 50%.

13. The method of claim 12, wherein oxygen is present in the atmosphere in an amount of about 10%.

14. The method of claim 13, wherein the atmosphere comprises about 30% nitrogen, about 10% oxygen and about 60% argon.

15. The method of any one of claims 11-14, wherein the sputter-coating of the silicon oxynitride layer includes using an aluminum-containing silicon target.

16. The method of claim 15, wherein the target includes about 8% by weight aluminum.
